(19) United States
(12) Patent Application Publication
(10) Pub. No.: US 2024/0159835 A1
(43) Pub. Date: May 16, 2024

(54) BATTERY MONITORING DEVICE AND PROGRAM

(71) Applicant: DENSO CORPORATION, Kariya-city (JP)

(72) Inventors: Masaki UCHIYAMA, Kariya-city (JP); Shunichi Kubo, Kariya-city (JP); Taisuke Kurachi, Kariya-city (JP); Yuuki Hori, Kariya-city (JP)

(73) Assignee: DENSO CORPORATION, Kariya-city (JP)

(21) Appl. No.: 18/423,449

(22) Filed: Jan. 26, 2024

Related U.S. Application Data
(63) Continuation of application No. PCT/JP22/25570, filed on Jun. 27, 2022.

(30) Foreign Application Priority Data
Jul. 27, 2021 (JP) 2021-122816

(51) Int. Cl. G01R 31/3835; G01R 31/378; G01R 31/396; H01M 4/58; H01M 4/583; H01M 10/42; H02J 7/00

(52) U.S. Cl. CPC G01R 31/3835; G01R 31/396; H01M 10/4285; H02J 7/0048; G01R 31/378; H01M 4/5825; H01M 4/583

(57) ABSTRACT

A battery monitoring device is applied to an assembled battery having a plurality of battery cells connected in series, the battery cells including a first battery cell and a second battery cell. The battery monitoring device includes: an acquisition unit configured to acquire, during charging or discharging of the battery cells, a battery parameter of each of the first and second battery cells, the battery parameter of each of the first and second battery cells being a terminal voltage across the corresponding one of the first and second battery cells or an impedance of the corresponding one of the first and second battery cells; and a state calculation unit configured to calculate a difference between the acquired battery parameter of the first battery cell and the acquired battery parameter of the second battery cell, and calculate a battery state of the battery cells based on the calculated difference.

### CROSS-REFERENCE TO RELATED APPLICATION

The present application is a continuation application of International Application No. PCT/JP2022/025570, filed Jun. 27, 2022, which claims priority to Japanese Patent Application No. 2021-122816 filed Jul. 27, 2021. The contents of these applications are incorporated herein by reference in their entirety.

### BACKGROUND

### Technical Field

The present disclosure relates to a battery monitoring device and program.

### Background Art

In batteries such as lithium ion batteries, there is a region in which a change in OCV (open circuit voltage) due to a change in SOC (state of charge) is small. This region is called a plateau region. In the plateau region, it is difficult to calculate the SOC of a battery using the SOC-OCV characteristics which indicate the correlation between the SOC and the open circuit voltage OCV.

### SUMMARY

In the present disclosure, provided is a battery monitoring device as the following.

The battery monitoring device is applied to an assembled battery having a plurality of battery cells connected in series, the battery cells including a first battery cell and a second battery cell. The battery monitoring device includes: an acquisition unit configured to acquire, during charging or discharging of the battery cells, a battery parameter of each of the first battery cell and the second battery cell, the battery parameter of each of the first battery cell and the second battery cell being a terminal voltage across the corresponding one of the first and second battery cells or an impedance of the corresponding one of the first and second battery cells; and a state calculation unit configured to calculate a difference between the acquired battery parameter of the first battery cell and the acquired battery parameter of the second battery cell, and calculate a battery state of the battery cells based on the calculated difference.

### BRIEF DESCRIPTION OF THE DRAWINGS

The above and other objects, features and advantages of the present disclosure will become apparent from the following detailed description with reference to the accompanying drawings. In the drawings:

FIG. 1 is an overall block diagram of a system according to a first embodiment;

FIG. 2 is a block diagram of a monitoring IC;

FIG. 3 is a diagram showing the relationship between voltage and capacity of a battery cell;

FIG. 4 is a flowchart showing a procedure of SOC calculation process;

FIGS. 5A to 5C are a joint timing chart showing the transition of terminal voltages of battery cells during charging, voltage difference and SOC of a battery cell;

FIG. 6 is a diagram showing a selection unit of a microcomputer according to a modification of the first embodiment;

FIG. 7 is a time chart showing the transition of terminal voltages of battery cells with the highest and lowest terminal voltages;

FIG. 8 is a flowchart showing a procedure of SOC calculation process according to a second embodiment;

FIGS. 9A to 9B are a joint timing char showing the transition of terminal voltages of battery cells during charging and voltage difference;

FIG. 10 is a flowchart showing a procedure of SOC calculation process according to a third embodiment;

FIGS. 11A to 11C are a joint timing char showing the transition of terminal voltages of battery cells during charging, voltage difference and the amount of voltage-time change;

FIG. 12 is a flowchart showing a procedure of capacity difference calculation process according to a fourth embodiment;

FIGS. 13A to 13E are a joint timing char showing the transition of terminal voltages of battery cells during charging, voltage difference, current integrated value, and the like;

FIG. 14 is a flowchart showing a procedure of SOC calculation process according to a fifth embodiment;

FIGS. 15A to 15D are a joint timing char the transition of SOC, terminal voltages, and the like of battery cells;

FIG. 16 is a diagram showing the relationship between the remaining capacity of a battery cell and the amount of voltage change according to a sixth embodiment;

FIG. 17 is a flowchart showing a procedure of SOC calculation process; and

FIGS. 18A to 18B are a joint timing chart showing the transition of impedance of battery cells and impedance difference.

### DETAILED DESCRIPTION OF THE PREFERRED EMBODIMENTS

PTL 1 describes the battery characteristics in which the amount of voltage change due to a capacity change of the battery is relatively large in part of the plateau region compared to other regions, while the amount of voltage change due to a capacity change is substantially constant in the other regions, and there is a phenomenon that an increase in the amount of voltage change due to a capacity change occurs in a specific SOC. PTL 1 describes a charge state estimation device that estimates the SOC of the battery using such characteristics. Specifically, the estimation device calculates the time-change rate of the detected terminal voltage of the battery when the state of the battery during charging or discharging is in the plateau region. When the estimation device determines that the calculated time-change rate is an inflection point that is upwardly convex, it determines that the current SOC of the battery is the SOC previously associated with the calculated time-change rate.

PTL 1: JP 6351852 B

Although the amount of voltage change due to a capacity change is relatively large in a part of the plateau region, the absolute value of the amount of voltage change is small. Therefore, if noise is superimposed on the detected terminal voltage of the battery, the accuracy of SOC calculation may be significantly reduced.

Furthermore, when calculating the battery state of the battery such as the remaining capacity of the battery, not only the SOC of the battery, the accuracy of battery state calculation may be significantly reduced due to noise.

An object of the present disclosure is to provide a battery monitoring device and program that can prevent a decrease in the accuracy of battery state calculation.

The present disclosure provides a battery monitoring device applied to an assembled battery having a plurality of battery cells connected in series, the battery cells including a first battery cell and a second battery cell, the battery monitoring device including: an acquisition unit configured to acquire, during charging or discharging of the battery cells, a battery parameter of each of the first battery cell and the second battery cell, the battery parameter of each of the first battery cell and the second battery cell being a terminal voltage across the corresponding one of the first and second battery cells or an impedance of the corresponding one of the first and second battery cells; and a state calculation unit configured to calculate a difference between the acquired battery parameter of the first battery cell and the acquired battery parameter of the second battery cell, and calculate a battery state of the battery cells based on the calculated difference.

The plurality of battery cells constituting the assembled battery are connected in series. Accordingly, when either the terminal voltage or impedance is used as the battery parameter, the degree of influence of noise on the battery parameter of each battery cell is considered to be the same. Therefore, a difference in battery parameters of two of the battery cells constituting the assembled battery is a value in which the influence of noise is reduced.

In view of the above, the state calculation unit of the present disclosure calculates a difference between the acquired battery parameter of the first battery cell and the acquired battery parameter of the second battery cell, and calculates a battery state of the battery cell based on the calculated difference. Accordingly, it is possible to prevent a decrease in the accuracy of battery state calculation.

### First Embodiment

With reference to the drawings, a first embodiment of a battery monitoring device according to the present disclosure will be described below. A system including the battery monitoring device of this embodiment is mounted to vehicles such as hybrid vehicles, electric vehicles and fuel cell vehicles. Examples of the vehicles include passenger vehicles, buses, construction vehicles and agricultural machinery vehicles. However, the system is not limited to a system mounted to a vehicle, and may be, for example, a stationary system.

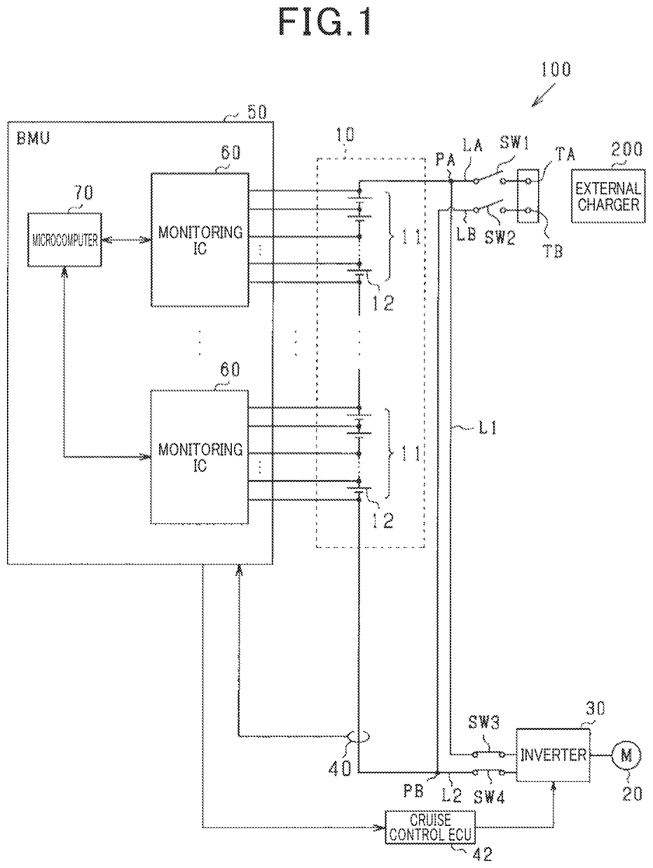

As shown in FIG. 1, a system 100 includes an assembled battery 10. The assembled battery 10 includes a series connection of a plurality of battery modules 11. Each battery module 11 includes a series connection of a plurality of battery cells 12. In this embodiment, the number of battery cells 12 included in each battery module 11 is the same. However, the number of battery cells 12 included in each battery module 11 may be different.

Each battery cell 12 is a rechargeable battery (secondary battery), and specifically a lithium ion battery. The lithium ion battery of this embodiment is an LFP battery in which lithium iron phosphate is used as a positive electrode active material and graphite is used as a negative electrode active material. Each of the battery cells 12 constituting the battery module 11 have the same rated voltage and the same rated capacity [Ah].

The system 100 includes a first charging path LA, a second charging path LB, a first external charging terminal TA, a second external charging terminal TB, a first switch SW1 and a second switch SW2. The first charging path LA connects the first external charging terminal TA to the positive electrode terminal of the battery cell on the highest potential-side among the battery cells 12 constituting the assembled battery 10. The second charging path LB connects the second external charging terminal TB to the negative electrode terminal of the battery cell on the lowest potential-side among the battery cells 12 constituting the assembled battery 10. The first charging path LA is provided with the first switch SW1, and the second charging path LB is provided with the second switch SW2.

When the first switch SW1 and the second switch SW2 are turned on, the assembled battery 10 is connected to an external charger 200 via the first and second external charging terminals TA and TB. The external charger 200 may be, for example, a DC quick charger. When the external charger 200 is connected to the first and second external charging terminals TA and TB, the assembled battery 10 is charged at a constant current or a constant voltage by high voltage DC power supplied from the external charger 200. For example, the assembled battery 10 may be charged at a constant current until just before it is fully charged, and then charged at a constant voltage. The external charger 200 may be an AC charger instead of a DC charger.

The system 100 includes a rotary electric machine 20, an inverter 30, a first electrical path L1, a second electrical path L2, a third switch SW3 and a fourth switch SW4. The first electrical path L1 connects a high potential-side terminal of the inverter 30 to a first connection point PA of the first charging path LA which is located closer to the assembled battery 10 than the first switch SW1 is. The second electrical path L2 connects a low potential-side terminal of the inverter 30 to a second connection point PB of the second charging path LB which is located closer to the assembled battery 10 than the second switch SW2 is. The first electrical path L1 is provided with the third switch SW3, and the second electrical path L2 is provided with the fourth switch SW4.

When the third switch SW3 and the fourth switch SW4 are turned on, the rotary electric machine 20 supplies and receives electrical power to and from the assembled battery 10 via the inverter 30. The rotary electric machine 20 provides a propulsive force to the vehicle using electrical power supplied from the assembled battery 10 during power running, and generates electrical power using deceleration energy of the vehicle during regeneration to supply electrical power to the assembled battery 10.

The system 100 includes a current sensor 40 and a BMU (Battery Management Unit) 50 as a battery monitoring device. The current sensor 40 detects a current flowing through the assembled battery 10. FIG. 1 shows that the current sensor 40 detects a current flowing through the second charging path LB. A value detected by the current sensor 40 is input to the BMU 50.

The BMU 50 turns on or off the first to fourth switches SW1 to SW4. Further, the BMU 50 is communicably connected to a cruise control ECU 42 via an in-vehicle network interface. The BMU 50 outputs commands to the cruise control ECU 42 to control the rotary electric machine 20 based on the remaining capacity [Ah] of the assembled battery 10. The cruise control ECU 42 performs switching control of the inverter 30 to control the control amount (e.g., torque) of the rotary electric machine 20 to a command value based on the command from the BMU 50.

The BMU 50 includes monitoring ICs 60 and a microcomputer 70, each monitoring IC 60 being provided corresponding to the corresponding one of the battery modules 11. The monitoring IC 60 detects the terminal voltage of each battery cell 12 constituting the battery module 11. The monitoring IC 60 exchanges information with the microcomputer 70. The microcomputer 70 acquires the terminal voltage detected by each monitoring IC 60 via an insulating element (not shown).

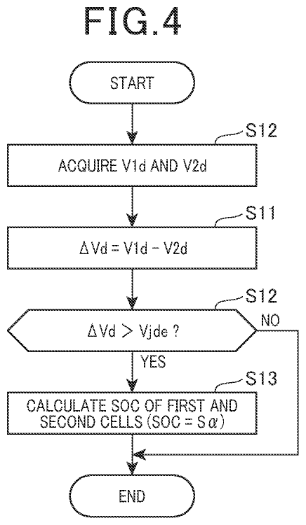

The microcomputer 70 includes a CPU. The functions provided by the microcomputer 70 can be provided by software recorded in a physical memory and a computer executing it, software alone, hardware alone, or a combination thereof. For example, when the microcomputer 70 is provided by an electronic circuit which is hardware, it can be provided by a digital circuit including a large number of logic circuits, or an analog circuit. For example, the microcomputer 70 executes a program stored in a non-transitory tangible storage medium as its own storage unit. The program may include, for example, a program of procedure shown in FIG. 4. By executing the program, a method corresponding to the program is executed. The storage unit may be, for example, a non-volatile memory. The programs stored in the storage unit can be updated via a network such as the internet, for example.

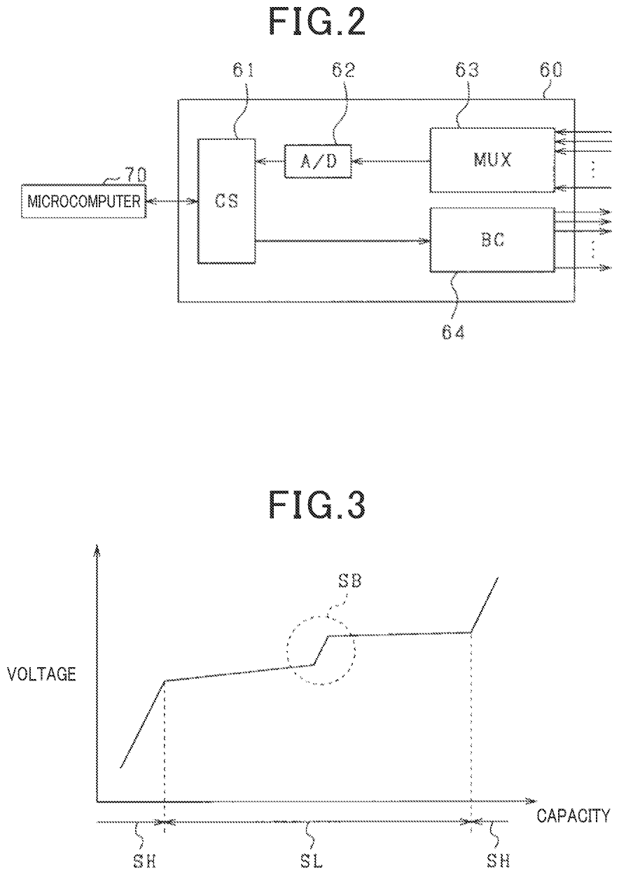

As shown in FIG. 2, the monitoring IC 60 includes a command unit 61, an A/D converter 62, a switch unit 63 and an equalization circuit unit 64. The command unit 61 has a function of interpreting a command from the microcomputer 70. The switch unit 63 has a function of arbitrarily selecting the voltage of each battery cell 12 and may be, for example, a multiplexer. The A/D converter 62 converts analog signals output from the switch unit 63 into digital signals. The converted digital signals are sent to the microcomputer 70 via the command unit 61. Thus, the microcomputer 70 acquires the terminal voltage of each battery cell 12. With the operation of these units, the monitoring IC 60 performs the process according to the command from the microcomputer 70. For example, the monitoring IC 60 can detect the terminal voltage of each battery cell 12 constituting the battery module 11 in a predetermined order.

The equalization circuit unit 64 performs an equalization process to reduce variations in voltage of the battery cells 12 constituting the battery module 11 based on a command from the microcomputer 70. The equalization circuit unit 64 is connected to each battery cell 12. The equalization process may be, for example, to discharge from the battery cell with the highest terminal voltage among the battery cells 12. For example, when the microcomputer 70 determines that a difference between the highest and lowest voltages among the detected terminal voltages of the battery cells 12 is greater than or equal to a predetermined voltage, it may transmit a command to the monitoring IC 60 to perform the equalization process.

As a method for calculating the remaining capacity of the assembled battery 10, there is a known method using SOC-OCV characteristics that shows the correlation between the state of charge (SOC) of the assembled battery 10 and the open circuit voltage (OCV). In this embodiment, however, an LFP battery is used as a lithium ion battery. As shown in FIG. 3, the LFP battery has a stable OCV over a wide range of remaining capacity, and has a plateau region SL in which a change in OCV due to a capacity change is small. On both ends of the plateau region SL, there are end regions SH in which a change in OCV due to a capacity change is larger than that in the plateau region SL. In the plateau region SL, it is difficult to calculate the SOC of the battery using the SOC-OCV characteristics to calculate the remaining capacity.

A part of the plateau region SL is a specific region SB in which a change in OCV due to a capacity change is relatively large. The specific region SB is a region caused by the negative electrode configuration of the battery cell 12. When the SOC of the battery cell 12 becomes a specific SOC or remaining capacity, the state of the battery cell 12 transitions to the specific region SB. Therefore, it can be determined that the current SOC or remaining capacity of the battery cell 12 is the specific SOC or remaining capacity when the state of the battery cell 12 transitions to the specific region SB. However, although the change in OCV is relatively large, the amount of change in OCV is small. Therefore, if noise is superimposed on the detected terminal voltage of the battery cell 12, the accuracy of SOC calculation may be significantly reduced. In order to address the above problem, in this embodiment, a procedure shown in FIG. 4 is performed while the assembled battery 10 is charged by the external charger 200, for example.

FIG. 4 is a flowchart of SOC calculation process of the battery cell 12 performed by the microcomputer 70. This process is repeatedly performed at a predetermined control cycle when it is determined that the state of the battery cell 12 is in the plateau region SL, for example. Whether it is in the plateau region SL may be determined based on the terminal voltage of the battery cell acquired from the monitoring IC 60.

In step S10, a terminal voltage of the first battery cell detected by the monitoring IC 60 (hereinafter, referred to as a first detected voltage V1d) and a terminal voltage of the second battery cell detected by the monitoring IC 60 (hereinafter, referred to as a second detected voltage V2d) are acquired. The first battery cell and the second battery cell are two battery cells selected from the battery cells 12 constituting the battery module 11. The method of selection will be further described below. The process in step S10 corresponds to an “acquisition unit”.

In step S11, a voltage difference ΔVd (corresponding to a “battery parameter”) is calculated by subtracting the second detected voltage V2d from the first detected voltage V1d.

In step S12, it is determined whether the calculated voltage difference ΔVd exceeds a determination value Vjde.

If an affirmative determination is made in step S12, the process proceeds to step S13, and the SOC of the first battery cell and the second battery cell is calculated as a specified value Sa. Note that the first and second battery cells among the battery cells 12 constituting the battery module 11 are not particularly limited, and for example, the SOC of each battery cell 12 may be calculated as a specified value Sa. In step S13, the remaining capacity of the first and second battery cells may be calculated instead of the SOC. The process in steps S11 to S13 correspond to a “state calculation unit”.

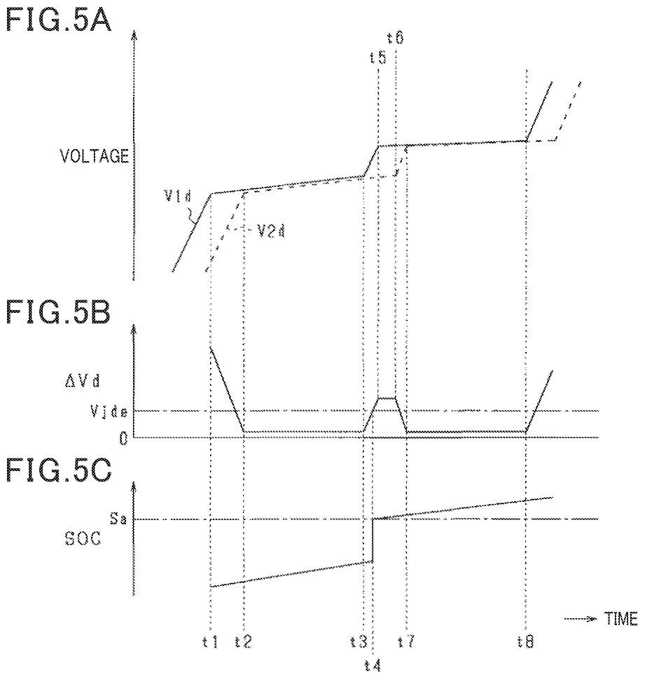

Referring to FIGS. 5A to 5C, the SOC calculation process will be described. FIG. 5A shows the transition of the first and second detected voltages V1d and V2d, FIG. 5B shows the transition of the voltage difference ΔVd, and FIG. 5C shows the transition of the SOC of the first battery cell. In the example shown in FIG. 5, the assembled battery 10 is charged (at a constant current or a constant voltage) by the external charger 200.

At time t1, the state of the first battery cell transitions from the end region SH to the plateau region SL, and the rate of increase in terminal voltage due to charging of the first battery cell decreases. At time t2, the state of the second battery cell transitions from the end region SH to the plateau region SL, and the rate of increase in terminal voltage due to charging of the second battery cell decreases. After time t2, since the first and second detected voltages V1d and V2d become equal, the voltage difference ΔVd becomes a value close to 0. The SOC of the first and second battery cells after time t1 may be a value calculated by the microcomputer 70 based on, for example, the initial SOC based on the open circuit voltage and the time integrated value of the charging current flowing through the first and second battery cells.

Then, at time t3, the state of the first battery cell transitions to the specific region SB, and from time t3 to time t5, the rate of increase in the first detected voltage V1d temporarily increases. Meanwhile, the state of the second battery cell is still in the plateau region SL. After time t3, the voltage difference ΔVd increases, and at time t4, the microcomputer 70 determines that the voltage difference ΔVd exceeds the determination value Vjde. Therefore, the microcomputer 70 calculates the SOC of the first and second battery cells as a specified value Sa. The determination value Vjde is set to a value that can determine that the current control cycle is an intermediate timing between time t3 and time t6. The SOC of the first and second battery cells after time t4 may be calculated by the microcomputer 70 based on, for example, the specified value Sa and the time integrated value of the charging current flowing through the first and second battery cells, respectively.

At time t6, the state of the second battery cell transitions to the specific region SB, and from time t6 to time t7, the rate of increase in the second detected voltage V2d temporarily increases. After time t7, since the first and second detected voltages V1d and V2d become equal, the voltage difference ΔVd becomes a value close to 0. As a result, from time t6, the rate of decrease in the voltage difference ΔVd increases, and at time t7, the voltage difference ΔVd becomes a value close to 0. At time t8, the state of the first battery cell transitions to the end region SH.

According to the present embodiment detailed above, the following effects can be achieved.

An instantaneous change in the current flowing through the assembled battery 10 generates noise, and the noise may be superimposed on the detected terminal voltage of each battery cell 12. The battery cells 12 constituting the assembled battery 10 are connected in series. Therefore, the degree of influence of noise on the detected terminal voltage of each battery cell 12 is considered to be the same. Accordingly, the voltage difference ΔVd, which is the difference between the detected terminal voltages of the first and second battery cells, is a value in which the influence of noise is reduced. Therefore, using the voltage difference ΔVd to estimate the SOC can prevent a decrease in the accuracy of SOC calculation even when noise occurs.

The monitoring IC 60 may be an IC in which either a full voltage range that the battery cell 12 can take or a limited voltage range which is a partial voltage range of the full voltage range can be set as a voltage detection range. When the limited voltage range is selected as the voltage detection range, the resolution of voltage detection is improved compared with the case where the full voltage range is selected as the voltage detection range. For example, the limited voltage range is preferably a voltage range of the battery cell 12 included in the plateau region SL. In this case, the accuracy of SOC calculation can be further improved. For example, when detecting a voltage of the battery cell 12 used in the procedure shown in FIG. 4, the microcomputer 70 sets a limited voltage range as the voltage detection range. However, selecting the limited voltage range as the voltage detection range causes the detected voltage to be susceptible to noise. According to the present embodiment that can reduce the influence of noise, it is not necessary that there be no influence of noise as the condition of voltage detection of the battery cell 12 in the plateau region SL. This mitigates restrictions on voltage detection.

### Modification of First Embodiment

The greater the variation in SOC of the battery cells 12 at the start of charging of the assembled battery 10, the greater the value the microcomputer 70 may set as the determination value Vjde. This setting is based on the fact that the greater the variation in SOC, the greater the peak value of the voltage difference ΔVd.

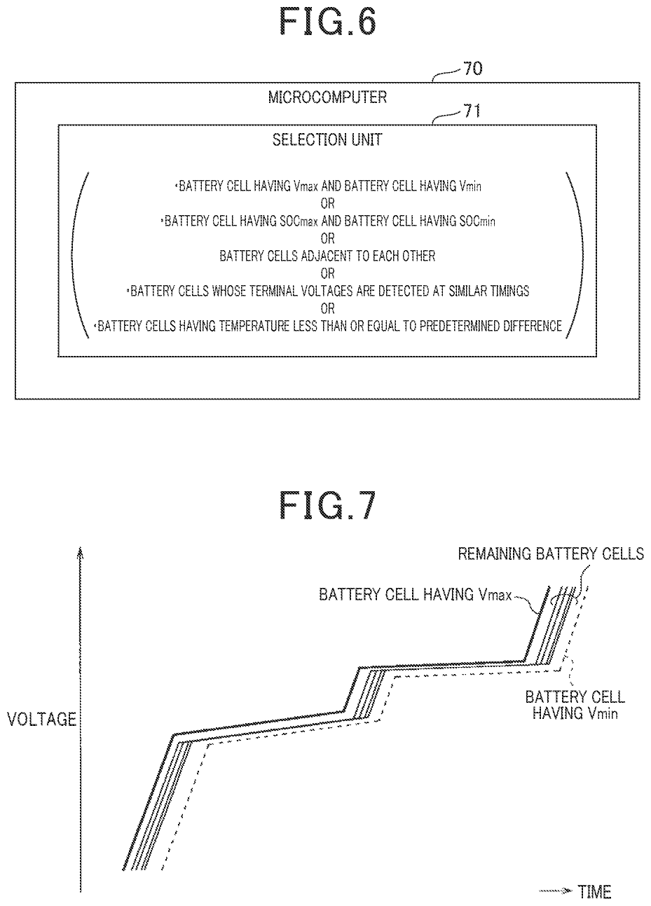

Further, the higher the temperature of the first and second battery cells or the smaller the charging current detected by the current sensor 40, the greater the value the microcomputer 70 may set as the determination value Vjde. This setting is based on the fact that the higher the temperature or the smaller the current, the greater the amount of increase in the detected voltage in the specific region SB.
As shown in FIG. 6, a selection unit 71 of the microcomputer 70 may select, from among the battery cells 12, a battery cell with the highest detected terminal voltage and a battery cell with the lowest detected terminal voltage as the first battery cell and the second battery cell, respectively. This increases the voltage difference ΔVd in the specific region SB as shown in FIG. 7, improving the accuracy of SOC calculation.

Furthermore, the selection unit 71 may select, from among the battery cells 12, a battery cell with the highest calculated SOC and a battery cell with the lowest calculated SOC as the first battery cell and the second battery cell, respectively.

Furthermore, the selection unit 71 may select, from among the battery cells 12, two battery cells connected in series and adjacent to each other as the first and second battery cells. Since the temperatures of two adjacent battery cells are close, the accuracy of SOC calculation based on the voltage difference ΔVd can be improved.

The first and second battery cells may be selected from among all the battery cells 12 constituting the assembled battery 10, may be selected from among the battery cells 12 constituting each battery module 11, or may be selected from among the battery cells 12 to be monitored by the same monitoring IC 60.
The selection unit 71 may select the first and second battery cells from among the battery cells 12 to be subjected to AD conversion by the same A/D converter 62. In this case, since the voltage detection errors of the battery cells 12 to be subjected to AD conversion are close to each other, the accuracy of SOC calculation can be improved.

Furthermore, the selection unit 71 may select, from among the battery cells 12 constituting the assembled battery 10, two battery cells with close detection timings as the first and second battery cells. In this case, since noise superimposed on the detected terminal voltages of the first and second battery cells are close to each other, the accuracy of SOC calculation can be improved.

Furthermore, the selection unit 71 may select, from among the battery cells 12 constituting the assembled battery 10, battery cells provided with a temperature sensor (for example, thermistor) as the first and second battery cells. Furthermore, the selection unit 71 may select, from among the battery cells 12 constituting the assembled battery 10, battery cells having a difference in temperature less than or equal to a predetermined temperature difference as the first and second battery cells.
In step S11, the voltage difference ΔVd may be calculated by subtracting the first detected voltage V1d from the second detected voltage V2d. In this case, the process in step S12 may be “|ΔVd|>Vjde?” or “ΔVd<Vjde? (where Vjde is a negative value)”.
The SOC calculation shown in FIG. 4 may be performed not only during charging of the assembled battery 10, but also during discharging of the assembled battery 10.

### Second Embodiment

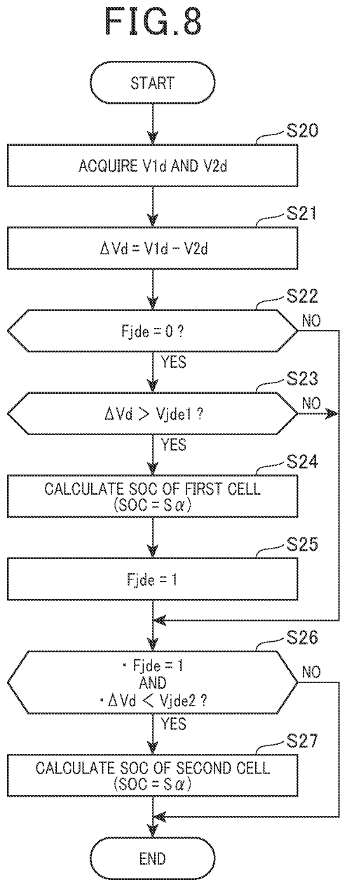

A second embodiment will be described below with reference to the drawings, mainly focusing on differences with the first embodiment. FIG. 8 shows a flowchart of SOC calculation process according to the present embodiment. This process is repeatedly performed by the microcomputer 70 at a predetermined control cycle when it is determined that the state of the battery cell 12 is in the plateau region SL, for example.

In step S20, a first detected voltage V1d and a second detected voltage V2d are acquired. In step S21, a voltage difference ΔVd is calculated by subtracting the second detected voltage V2d from the first detected voltage V1d.

In step S22, it is determined whether a determination flag Fjde is 0.

If it is determined that the determination flag Fjde is 0 in step S22, the process proceeds to step S23, and it is determined whether the calculated voltage difference ΔVd exceeds a first determination value Vjde1. If a negative determination is made in step S23, the process proceeds to step S26.

If an affirmative determination is made in step S23, the process proceeds to step S24, and the SOC of the first battery cell is calculated as a specified value Sa. In step S24, the remaining capacity of the first battery cell may be calculated instead of the SOC.

After completion of the process at step S24, the process proceeds to step S25, and the determination flag Fjde is set to 1. Then, the process proceeds to step S26.

In step S26, it is determined whether both the conditions that the determination flag Fjde is 1 and that the calculated voltage difference ΔVd is below the second determination value Vjde2 are satisfied. In this embodiment, the second determination value Vjde2 is set to a value smaller than the first determination value Vjde1. However, the above is merely an example, and the second determination value Vjde2 may be set to a value greater than the first determination value Vjde1 or the same value as the first determination value Vjde1.

If an affirmative determination is made in step S26, the process proceeds to step S27, and the SOC of the second battery cell is calculated as a specified value Sa. In step S27, the remaining capacity of the second battery cell may be calculated instead of the SOC.

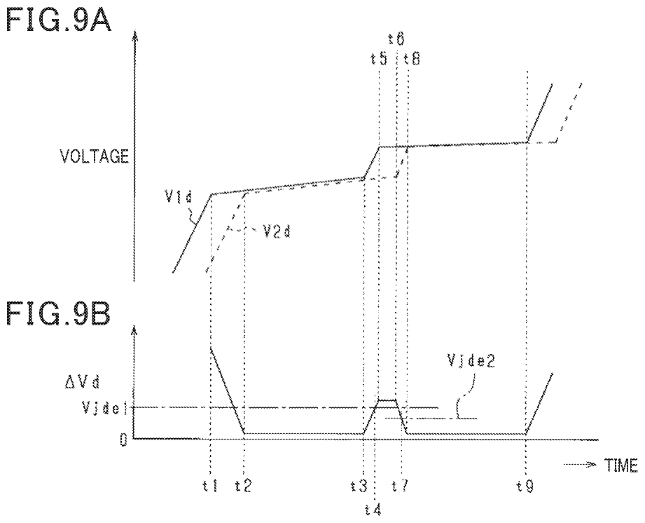

Referring to FIGS. 9A to 9B, the SOC calculation process will be described. FIGS. 9A and 9B correspond to the foregoing FIGS. 5A and 5B, respectively. In the example shown in FIGS. 9A to 9B, the assembled battery 10 is charged (at a constant current or a constant voltage) by the external charger 200.

At time t1, the state of the first battery cell transitions from the end region SH to the plateau region SL, and at time t2, the state of the second battery cell transitions from the end region SH to the plateau region SL. After time t2, since the first and second detected voltages V1d and V2d become equal, the voltage difference ΔVd becomes a value close to 0.

Then, at time t3, the state of the first battery cell transitions to the specific region SB, and from time t3 to time t5, the rate of increase in the first detected voltage V1d temporarily increases. Meanwhile, the state of the second battery cell is still in the plateau region SL. After time t3, the voltage difference ΔVd increases, and at time t4, the microcomputer 70 determines that the voltage difference ΔVd exceeds the first determination value Vjde1. Therefore, the microcomputer 70 calculates the SOC of the first battery cell as a specified value Sα.

At time t6, the state of the second battery cell transitions to the specific region SB, and from time t6 to time t8, the rate of increase in the second detected voltage V2d temporarily increases. As a result, at time t7, the microcomputer 70 determines that the voltage difference ΔVd has fallen below the second determination value Vjde2. Therefore, the microcomputer 70 calculates the SOC of the second battery cell as a specified value Sα. At time t9, the state of the first battery cell transitions to the end region SH.

According to the present embodiment described in detail above, the SOC of the first and second battery cells can be individually calculated.

### Third Embodiment

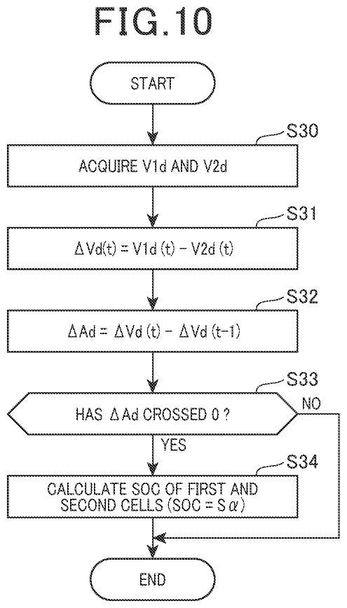

A third embodiment will be described below with reference to the drawings, mainly focusing on differences with the first embodiment. FIG. 10 shows a flowchart of SOC calculation process according to the present embodiment. This process is repeatedly performed by the microcomputer 70 at a predetermined control cycle when it is determined that the state of the battery cell 12 is in the plateau region SL, for example.

In step S30, a first detected voltage V1d(t) and a second detected voltage V2d(t) are acquired.

In step S31, a voltage difference ΔVd(t) in the current control cycle is calculated by subtracting the second detected voltage V2d(t) acquired in the current control cycle from the first detected voltage V1d(t) acquired in the current control cycle.

In step S32, an amount of voltage-time change ΔAd is calculated by subtracting the voltage difference ΔVd(t−1) calculated in the previous control cycle from the voltage difference ΔVd(t) calculated in the current control cycle.

In step S33, it is determined whether the amount of voltage-time change ΔAd has crossed 0.

If an affirmative determination is made in step S33, the process proceeds to step S34, and the SOC of the first battery cell and the second battery cell is calculated as a specified value Sα. In step S34, the remaining capacity of the first and second battery cells may be calculated instead of the SOC.

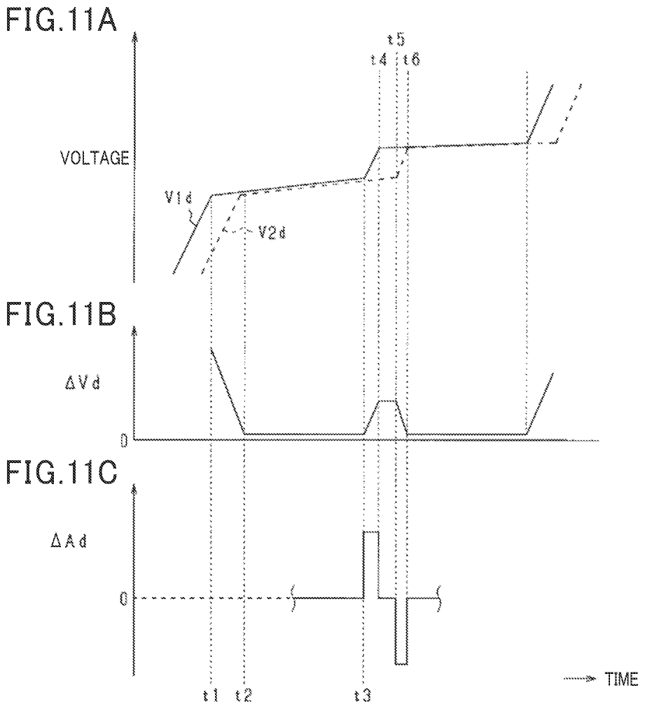

Referring to FIGS. 11A to 11C, the SOC calculation process will be described. FIGS. 11A and 11B correspond to the foregoing FIGS. 5A and 5B, respectively, and FIG. 11C shows the transition of the amount of voltage-time change ΔAd. In the example shown in FIGS. 11A to 11C, the assembled battery 10 is charged (at a constant current or a constant voltage) by the external charger 200.

At time t1, the state of the first battery cell transitions from the end region SH to the plateau region SL, and at time t2, the state of the second battery cell transitions from the end region SH to the plateau region SL. After time t2, since the first and second detected voltages V1d and V2d become equal, the voltage difference ΔVd becomes a value close to 0, and the amount of voltage-time change ΔAd becomes 0 or a positive value close to 0.

Then, at time t3, the state of the first battery cell transitions to the specific region SB, and from time t3 to time t5, the rate of increase in the first detected voltage V1d temporarily increases. As a result, the amount of voltage-time change ΔAd increases to the positive side.

Then, from time t4 to time t5, the amount of voltage-time change ΔAd becomes 0 or a positive value close to 0. At time t5, the state of the second battery cell transitions to the specific region SB, and from time t5 to time t6, the rate of increase in the second detected voltage V2d temporarily increases. As a result, the amount of voltage-time change ΔAd greatly changes to the negative side. Accordingly, at time t5, the microcomputer 70 determines that the amount of voltage-time change ΔAd has crossed 0. Therefore, the microcomputer 70 calculates the SOC of the first and second battery cells as a specified value Sα.

According to the present embodiment described above, the same effects as those in the first embodiment can be achieved.

### Modification of Third Embodiment

Referring to FIG. 11, for example, the microcomputer 70 may calculate the SOC of the first and second battery cells as a specified value Sa at time t4 at which the amount of voltage-time change ΔAd greatly decreases to a value close to 0.
Instead of the amount of voltage-time change ΔAd, the following parameters (A) and (B) may be used.

(ΔVd(tm)−ΔVd(tm−1))/ΔCa (A)

ΔCa indicates the amount of capacity change [Ah] of the battery cell during a specified period from time tm−1 to time tm. The specified period may be, for example, a single control cycle of the microcomputer 70 or a period longer than a single control cycle. The specified period may be set, for example, as a period required for the amount of capacity change ΔCa to become a predetermined amount of capacity change. ΔVd(tm−1) is a value obtained by subtracting the second detected voltage V2d acquired at time tm−1 from the first detected voltage V1d acquired at time tm−1. ΔVd(tm) is a value obtained by subtracting the second detected voltage V2d acquired at time tm from the first detected voltage V1d acquired at time tm.

(ΔVd(tm)−ΔVd(tm−1))/ΔSOC (B)

ΔSOC indicates the amount of change in SOC of the battery cell during a specified period from time tm−1 to time tm. The specified period in this case may be set, for example, as a period required for the amount of SOC change ΔSOC to become a predetermined amount of SOC change.

### Fourth Embodiment

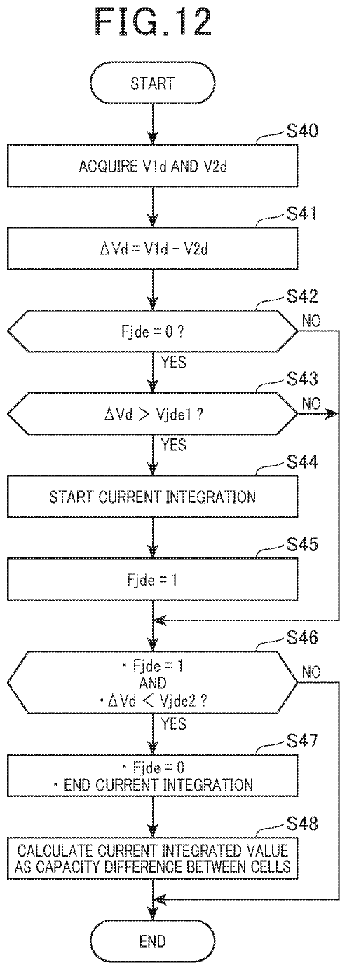

A fourth embodiment will be described below with reference to the drawings, mainly focusing on differences with the first embodiment. In this embodiment, a difference in remaining capacity of the first and second battery cells is calculated instead of the SOC. FIG. 12 shows a flowchart of a process of remaining capacity difference calculation. This process is repeatedly performed by the microcomputer 70 at a predetermined control cycle when it is determined that the state of the battery cell 12 is in the plateau region SL, for example.

In step S40, a first detected voltage V1d and a second detected voltage V2d are acquired. In step S41, a voltage difference ΔVd is calculated by subtracting the second detected voltage V2d from the first detected voltage V1d.

In step S42, it is determined whether a determination flag Fjde is 0. If it is determined that the determination flag Fjde is 0 in step S42, the process proceeds to step S43, and it is determined whether the calculated voltage difference ΔVd exceeds a first determination value Vjde1. If an affirmative determination is made in step S43, that is, if it is determined that the voltage difference ΔVd has changed in the positive direction and crossed the first determination value Vjde1, the process proceeds to step S44 and starts calculating a time integrated value of the charging current detected by the current sensor 40. After completion of the process at step S44, the process proceeds to step S45, and the determination flag Fjde is set to 1. Then, the process proceeds to step S46.

In step S46, it is determined whether the first condition that the determination flag Fjde is 1 and the second condition that the calculated voltage difference ΔVd is below the second determination value Vjde2 are satisfied. In other words, the second condition is a condition that the voltage difference ΔVd has changed in the negative direction and crossed the second determination value Vjde2.

If an affirmative determination is made in step S46, the process proceeds to step S47, in which the determination flag Fjde is set to 0 and the current integration process started in step S44 is terminated. In step S47, the time integrated value of the charging current calculated in the current integration process is calculated as a difference in remaining capacity between the first and second battery cells. Further, a difference in SOC between the first and second battery cells may be calculated based on the difference in remaining capacity.

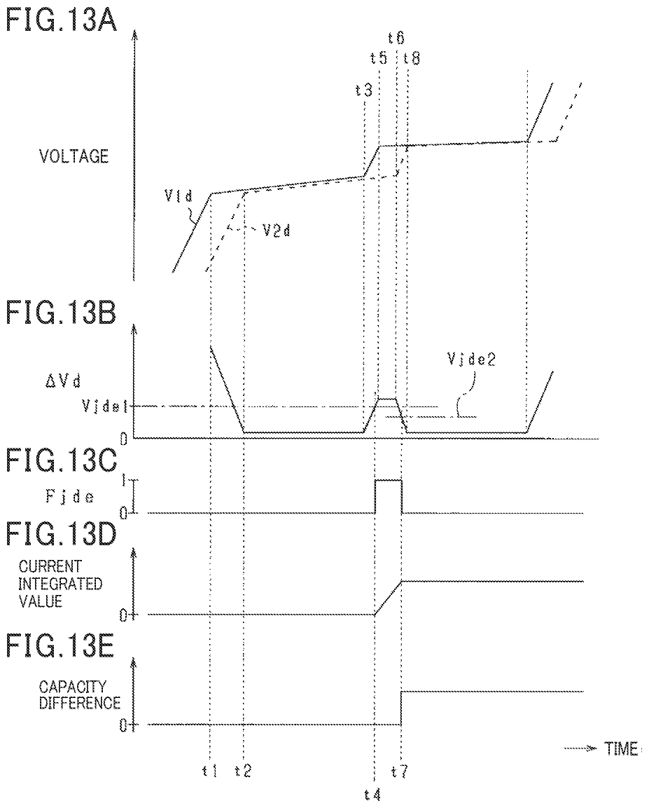

Referring to FIGS. 13A to 13E, a process of calculating a difference in remaining capacity will be described. FIGS. 13A and 13B correspond to the foregoing FIGS. 5A and 5B, respectively. FIG. 13C shows the transition of the determination flag Fjde, FIG. 13D shows the transition of the time integrated value of the charging current, and FIG. 13E shows the transition of the difference in remaining capacity between the first and second battery cells. In the example shown in FIGS. 13A to 13E, the assembled battery 10 is charged (at a constant current or a constant voltage) by the external charger 200.

At time t1, the state of the first battery cell transitions from the end region SH to the plateau region SL, and at time t2, the state of the second battery cell transitions from the end region SH to the plateau region SL.

Then, at time t3, the state of the first battery cell transitions to the specific region SB, and from time t3 to time t5, the rate of increase in the first detected voltage V1d temporarily increases. At time t4, the microcomputer 70 determines that the voltage difference ΔVd exceeds the first determination value Vjde1. Therefore, the determination flag Fjde is set to 1 and the integration process of the charging current is started.

At time t6, the state of the second battery cell transitions to the specific region SB, and from time t6 to time t8, the rate of increase in the second detected voltage V2d temporarily increases. As a result, at time t7, the microcomputer 70 determines that the voltage difference ΔVd has fallen below the second determination value Vjde2. Therefore, the determination flag Fjde is set to 0 and the integration process of the charging current is terminated. Then, the value of the charging current accumulated from time t4 to time t7 is calculated as a difference in remaining capacity between the first and second battery cells.

In addition, when the microcomputer 70 determines that the calculated difference in remaining capacity is greater than or equal to a predetermined capacity, it may determine that at least one of the first and second battery cells is malfunctioning. Further, based on the calculated difference in remaining capacity, the microcomputer 70 may determine the amount of discharge of the battery cells in the equalization process.

### Fifth Embodiment

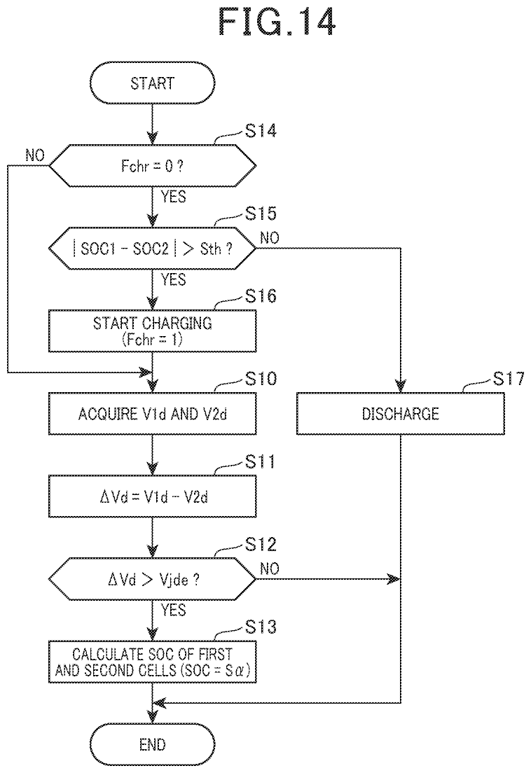

A fifth embodiment will be described below with reference to the drawings, mainly focusing on differences with the first embodiment. In this embodiment, if the difference in SOC between the first and second battery cells is small, a process to increase the difference is performed prior to the SOC calculation process as shown in FIG. 14. In FIG. 14, the same processes as those in the foregoing FIG. 4 are indicated by the same reference numbers for convenience.

In step S14, it is determined whether a charge start flag Fchr is 0. The charge start flag Fchr indicates that charging of the assembled battery 10 has not yet started when it is 0 and indicates that charging has been started when it is 1. If it is determined that the charge start flag Fchr is 1 in step S14, the process proceeds to step S10.

On the other hand, if it is determined that the charge start flag Fchr is 0 in step S14, the process proceeds to step S15, and it is determined whether the absolute value of the difference between the SOC of the first battery cell (hereinafter, SOC1) and the SOC of the second battery cell (hereinafter, SOC2) is greater than a threshold Sth. If an affirmative determination is made in step S15, the process proceeds to step S16, in which the charge start flag Fchr is set to 1 and charging of the assembled battery 10 by the external charger 200 is started. In this embodiment, SOC1 and SOC2 correspond to “storage amount parameters”. The storage amount parameters are not limited to the SOC1 and SOC2, and may be, for example, the first and second detected voltages V1d and V2d or the remaining capacities of the first and second battery cells.

On the other hand, if a negative determination is made in step S15, the process proceeds to step S17, and a discharging process is performed in which either the first or second battery cell is discharged. In this embodiment, the second battery cell is discharged. The equalization circuit unit 64 may be used for this discharge. This discharge continues until an affirmative determination is made in step S15.

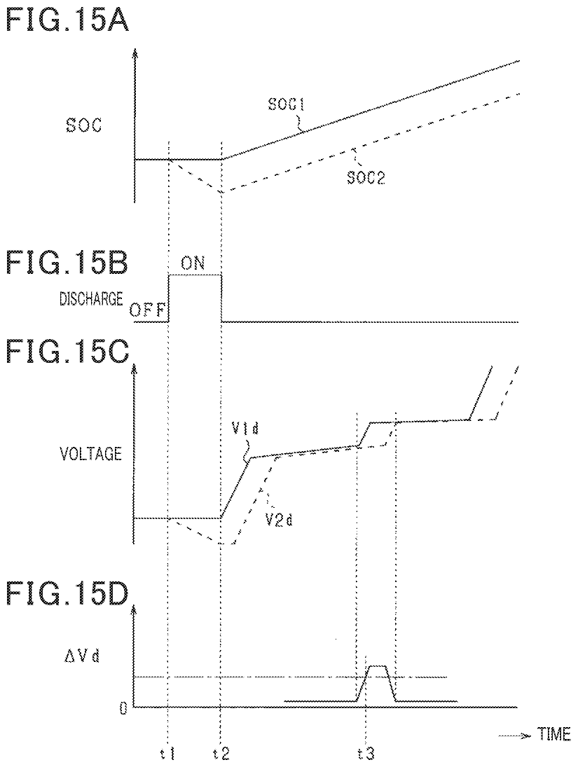

Referring to FIGS. 15A to 15D, the above-mentioned process will be further described. FIG. 15A shows the transition of SOC1 and SOC2, FIG. 15B shows whether the discharging process of the second battery cell is performed. FIGS. 15C and 15D correspond to the foregoing FIGS. 5A and 5B, respectively.

At time t1, the microcomputer 70 determines that the absolute value of the difference between SOC1 and SOC2 is less than or equal to the threshold Sth. Therefore the microcomputer 70 performs the discharging process until time t2 at which it is determined that the absolute value has exceeded the threshold Sth. Then, the charging process of the assembled battery 10 is started, and a process of estimating SOC is performed. At time t3, the microcomputer 70 determines that the voltage difference ΔVd has exceeded the determination value Vjde, and calculates the SOC of the first battery cell as a specified value Sα.

When the difference between SOC1 and SOC2 is small, the voltage difference ΔVd calculated in the SOC calculation process is small, which may reduce the accuracy of SOC calculation. Therefore, in this embodiment, a discharging process is performed prior to the SOC calculation process. As a result, the SOC calculation process can be started with the difference between SOC1 and SOC2 being increased, preventing a decrease in the accuracy of SOC calculation.

The discharging process to increase the difference between SOC1 and SOC2 may not necessarily be performed before charging the assembled battery 10. For example, the microcomputer 70 may calculate the absolute value of the difference between SOC1 and SOC2 each time during charging of the assembled battery 10, and if it is determined that the calculated absolute value has become a value less than or equal to the threshold Sth, the microcomputer 70 may perform the process of step S17 while charging the assembled battery 10.

### Modifications of Fifth Embodiment

The above-mentioned threshold Sth is set as a first threshold Sth1, and a value greater than the first threshold Sth1 is set as a second threshold Sth2. In this case, the microcomputer 70 may perform the discharging process for a period from the time when the absolute value of the difference between SOC1 and SOC2 is determined to be less than or equal to the first threshold Sth1 to the time when the above absolute value is determined to be greater than or equal to the second threshold Sth2.
The discharging process of step S17 in FIG. 14 may be changed to a charging process that charges either the first or second battery cell for a period from the time when a negative determination is made in step S15 to the time when an affirmative determination is made in step S15.

Furthermore, one of the first and second battery cells may be discharged and the other may be charged to increase the difference in SOC between the first and second battery cells.

### Sixth Embodiment

A sixth embodiment will be described below with reference to the drawings, mainly focusing on differences with the first embodiment. In this embodiment, instead of the terminal voltage of the battery cell, an impedance of the battery cell is used as the battery parameter. The reason for using the impedance will be described below.

In a battery, an amount of reaction heat WR changes as the remaining capacity changes due to energization. The amount of reaction heat WR is obtained by subtracting a Joule heat WJ due to the impedance component of the battery from an amount of heat WB of the battery due to energization as shown in the following formula (1). The amount of reaction heat WR is expressed using a temperature TM of the battery, a charging and discharging current IS, and an amount of voltage change ΔOCV which is the amount of change in open circuit voltage OCV per unit temperature as shown in the following formula (2).

WB=WJ+WR (1)

WR=TM×IS×ΔOCV (2)

According to formula (2), the amount of reaction heat WR is proportional to the amount of voltage change ΔOCV. The amount of voltage change ΔOCV has a value for each battery capacity, and in some storage batteries, the amount of voltage change ΔOCV changes as the capacity changes. In such batteries, when the capacity changes, the amount of reaction heat WR changes, and thus the temperature TM changes. Moreover, in batteries, the temperature TM and impedance have a correlation. Therefore, when the temperature TM of the battery changes, the impedance of the battery changes.

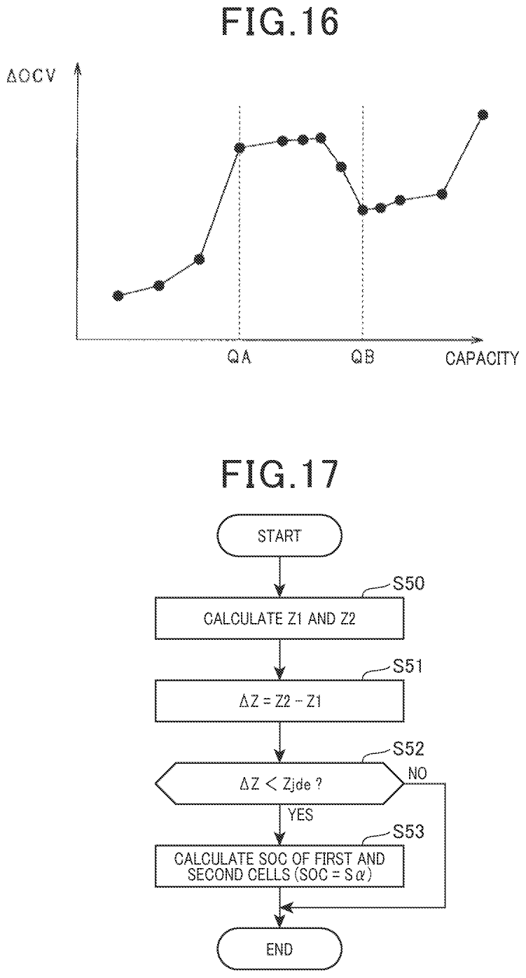

FIG. 16 shows the relationship between the remaining capacity of the battery cell 12 and the amount of voltage change ΔOCV according to the present embodiment. As shown in FIG. 16, the battery cell 12 has a specific capacity region from a first capacity QA to a second capacity QB, and the specific capacity region is included in the plateau region SL. When the remaining capacity crosses the first capacity QA from a low capacity side, the amount of voltage change ΔOCV steeply increases, and when the remaining capacity crosses the second capacity QB from a low capacity side, the amount of voltage change ΔOCV steeply decreases. Since the change in the amount of voltage change ΔOCV at the first and second capacities QA and QB is steep, the tendency of the impedance transition of the battery cell 12 during energization changes as it crosses the first and second capacities QA and QB. FIG. 17 shows the SOC calculation process focusing on this point. This process is repeatedly performed by the microcomputer 70 at a predetermined control cycle when it is determined that the state of the battery cell 12 is in the plateau region SL, for example.

In step S50, an impedance Z1 of the first battery cell and an impedance Z2 of the second battery cell are calculated. Taking the example of the first battery cell, an impedance Z1 of the first battery cell is calculated by dividing the amount of change ΔV1 of the first detected voltage V1d when the charging current flowing through the first battery cell changes during charging of the assembled battery 10 by the amount of change ΔIS of the charging current.

In step S51, an impedance difference ΔZ is calculated by subtracting the impedance Z1 of the first battery cell from the impedance Z2 of the second battery cell. The impedance difference ΔZ is a value in which the influence of noise is reduced. In step S52, it is determined whether the impedance difference ΔZ is below the determination value Zjde. If an affirmative determination is made in step S52, the process proceeds to step S53, and the SOC of the first battery cell and the second battery cell is calculated as a specified value Sα. In step S53, the remaining capacity of the first and second battery cells may be calculated instead of the SOC.

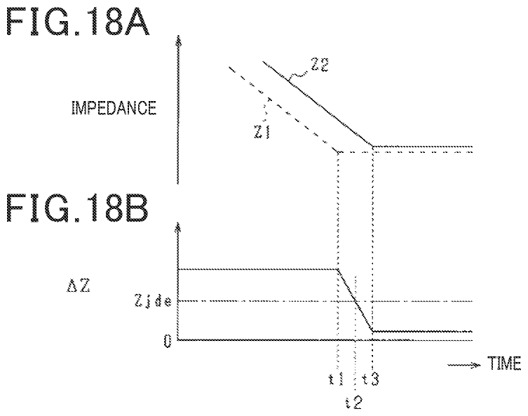

Referring to FIGS. 18A to 18B, the SOC calculation process will be described. FIG. 18A shows the transition of the impedances Z1 and Z2 of the first and second battery cells, and FIG. 18B shows the transition of the impedance difference ΔZ. In the example shown in FIGS. 18A to 18B, the assembled battery 10 is charged by the external charger 200.

When the states of the first and second battery cells are in the plateau region SL, the impedance difference ΔZ is substantially constant until time t1. At time t1, the impedance difference ΔZ begins to decrease, and at time t2, the microcomputer 70 determines that the impedance difference ΔZ has fallen below the determination value Zjde. Therefore, the microcomputer 70 calculates the SOC of the first and second battery cells as a specified value Sα. At time t3, the large drop in the impedance of the second battery cell stops, and the impedance difference ΔZ becomes substantially constant thereafter.

According to the present embodiment described above, the same effects as those in the first embodiment can be achieved.

### Other Embodiments

Here, the above-described embodiments may be modified in the following manner
Referring to FIGS. 18A to 18B, the microcomputer 70 may calculate the SOC of the first battery cell as a specified value Sa at time t1, and may calculate the SOC of the second battery cell as a specified value Sa at time t2.
In the second to fifth embodiments, the impedance difference ΔZ may be used instead of the voltage difference ΔVd.
The control unit and the method thereof described in the present disclosure may be implemented by a dedicated computer that is configured by a processor and a memory, the processor being programmed to provide one or a plurality of functions that are realized by a computer program. Alternatively, the control unit and the method thereof described in the present disclosure may be implemented by a dedicated computer that is provided by a processor being configured by a single dedicated hardware logic circuit or more. Alternatively, the control unit and the method thereof described in the present disclosure may be implemented by a single dedicated computer or more, the dedicated computer being configured by a combination of a processor that is programmed to provide one or a plurality of functions, a memory, and a processor that is configured by a single hardware logic circuit or more. In addition, the computer program may be stored in a non-transitory tangible recording medium that can be read by a computer as instructions performed by the computer.

Although the present disclosure has been described in accordance with the examples, the present disclosure should not be construed as limited to those examples or structures. The present disclosure encompasses various modifications and equivalent alterations. In addition, various combinations and forms, and other combinations and forms including only one element, one or more elements, or one or less elements are also within the scope and spirit of the present disclosure.

What is claimed is:

1. A battery monitoring device applied to an assembled battery having a plurality of battery cells connected in series, the battery cells including a first battery cell and a second battery cell, the battery monitoring device comprising:
an acquisition unit configured to acquire, during charging or discharging of the battery cells, a battery parameter of each of the first battery cell and the second battery cell, the battery parameter of each of the first battery cell and the second battery cell being a terminal voltage across the corresponding one of the first and second battery cells or an impedance of the corresponding one of the first and second battery cells; and
a state calculation unit configured to calculate a difference between the acquired battery parameter of the first battery cell and the acquired battery parameter of the second battery cell, and calculates a battery state of the battery cells based on the calculated difference.

2. The battery monitoring device according to claim 1, wherein
the battery state of the battery cells is a SOC or a remaining capacity of the battery cells, and
while the state of the first battery cell and the state of the second battery cell are in a plateau region, the state calculation unit is configured to calculate a SOC or a remaining capacity of the battery cells as a specified value when it is determined that the calculated difference has crossed a determination value.

3. The battery monitoring device according to claim 1, wherein
the battery state of the battery cells is a SOC or a remaining capacity of the battery cells, and
the state calculation unit is configured to:
calculate an amount of change of the calculated difference, and
while the state of the first battery cell and the state of the second battery cell are in a plateau region, calculate a SOC or a remaining capacity of the battery cells as a specified value when the calculated amount of change is near a predetermined value.

4. The battery monitoring device according to claim 1, wherein
the battery state of the battery cells is (i) a difference between a SOC of the first battery cell and a SOC of the second battery cell or (ii) a difference between a remaining capacity of the first battery cell and a remaining capacity of the second battery cell, and
while the state of the first battery cell and the state of the second battery cell are in a plateau region, the state calculation unit is configured to:
calculate a time integrated value of a current flowing through the battery cells during a period from a time when the calculated difference changes in a first direction and crosses a first determination value to a time when the calculated difference changes in a second direction opposite to the first direction and crosses a second determination value, and
calculate (i) the difference between a SOC of the first battery cell and a SOC of the second battery cell or (ii) the difference between a remaining capacity of the first battery cell and a remaining capacity of the second battery cell based on the calculated time integrated value.

5. The battery monitoring device according to claim 1, wherein
the state calculation unit is configured to:
calculate a difference between a storage amount parameter of the first battery cell and a storage amount parameter of the second battery cell, the storage amount parameter being any of a SOC, a remaining capacity and a terminal voltage, and
if the calculated difference is less than a threshold, discharge or charge at least one of the first battery cell and the second battery cell until the calculated difference becomes greater than the threshold.

6. The battery monitoring device according to claim 1, wherein
the first battery cell and the second battery cell have one of the following first to fifth features:
the first feature is that the terminal voltage across one of the first and second battery cells is the highest in the plurality of battery cells and the terminal voltage of the other of the first and second battery cells is the lowest in the plurality of battery cells;
the second feature is that an SOC of one of the first and second battery cells is the highest in the plurality of battery cells and an SOC of the other of the first and second battery cells is the lowest in the plurality of battery cells;
the third feature is that the first and second battery cells are located adjacent to one another;
the fourth feature is that a detection timing of the terminal voltage across the first battery cell is close to a detection timing of the terminal voltage across the second battery cell; and
the fifth feature is that the first and second battery cells have a difference in temperature that is lower than or equal to a predetermined temperature difference.

7. The battery monitoring device according to claim 1, wherein a negative electrode of each of the battery cells contains graphite.

8. The battery monitoring device according to claim 1, wherein a positive electrode of each of the battery cells contains lithium iron phosphate.

9. A non-transitory computer-readable storage medium storing a program applied to a system which includes an assembled battery and a computer, the assembled battery having a plurality of battery cells connected in series, the battery cells including a first battery cell and a second battery cell, the program causing the computer to execute:
during charging or discharging of the battery cells, acquiring a battery parameter of each of the first battery cell and the second battery cell, the battery parameter of each of the first battery cell and the second battery cell being a terminal voltage across the corresponding one of the first and second battery cells or an impedance of the corresponding one of the first and second battery cells; and
calculating a difference between the acquired battery parameter of the first battery cell and the acquired battery parameter of the second battery cell, and calculating a battery state of the battery cells based on the calculated difference.
